(19) United States
(12) Patent Application Publication
(10) Pub. No.: US 2021/0327661 A1
(43) Pub. Date: Oct. 21, 2021

(54) KEYBOARD HAVING TOUCH-SENSITIVE KEYCAPS WHICH ARE ALSO PRESSABLE AND METHOD FOR MAKING SAME

(71) Applicant: HON HAI PRECISION INDUSTRY CO., LTD., New Taipei (TW)

(72) Inventors: YUAN-HUNG CHIEN, New Taipei (TW); REN-YI HUANG, New Taipei (TW); CHANG-HSUN TU, New Taipei (TW)

(21) Appl. No.: 16/895,136

(22) Filed: Jun. 8, 2020

(30) Foreign Application Priority Data
Apr. 20, 2020 (CN) 202010314315.9

(51) Int. Cl. H01H 13/705; H01H 13/83

(52) U.S. Cl. CPC H01H 13/705; H01H 13/83; H01H 2219/036; H01H 2203/052; H01H 2239/074

(57) ABSTRACT

A keyboard able to recognize fingertip touches and touches in gestures such as fingertip sliding, in addition to simple presses on keycaps, includes a plurality of keycaps, a touch layer, a function trigger layer, a touch controller, and a function controller. Each keycap has an operation surface for receiving the pressings and touches. The touch layer generates touch sensing signals according to the touches, the function component generates key signals according to the pressings. The touch controller obtains touch information from the touch sensing signals. The function controller triggers desired key functions according to the key signals received. A method for making such keyboard is also disclosed.

### FIELD

The subject matter herein generally relates to human-computer interface devices, particularly a keyboard and a method for making the keyboard.

### BACKGROUND

As a human-computer interaction tool, a keyboard is used to input user commands to an electronic device (such as a computer).

A traditional keyboard includes multiple keys. A user can trigger different functions of an electronic device connected with the keyboard by pressing different keys.

### BRIEF DESCRIPTION OF THE DRAWINGS

Implementations of the present disclosure will now be described, by way of embodiment, with reference to the attached figures.

FIG. 1 is an isometric view of a keyboard and an electronic device according to an embodiment of the present disclosure.

FIG. 2 is a cross-sectional view of a keycap of the keyboard shown in FIG. 1.

FIG. 3 is a planar view of a substrate and a touch layer of the keyboard shown in FIG. 1.

FIG. 4 is a flow chart of a method for making the keyboard according to an embodiment of the present disclosure.

FIG. 5A is a planar view of the keyboard in block S1 and block S2.

FIG. 5B is a cross-sectional view of the keyboard in the block S1 and the block S2.

FIG. 6A is a planar view of the keyboard in block S3.

FIG. 6B is a cross-sectional view of the keyboard in the block S3.

FIG. 7A is another planar view of the keyboard in block S3.

FIG. 7B is another cross-sectional view of the keyboard in the block S3.

FIG. 8A is another planar view of the keyboard in block S3.

FIG. 8B is another cross-sectional view of the keyboard in the block S3.

### DETAILED DESCRIPTION

It will be appreciated that for simplicity and clarity of illustration, where appropriate, reference numerals have been repeated among different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series, and the like.

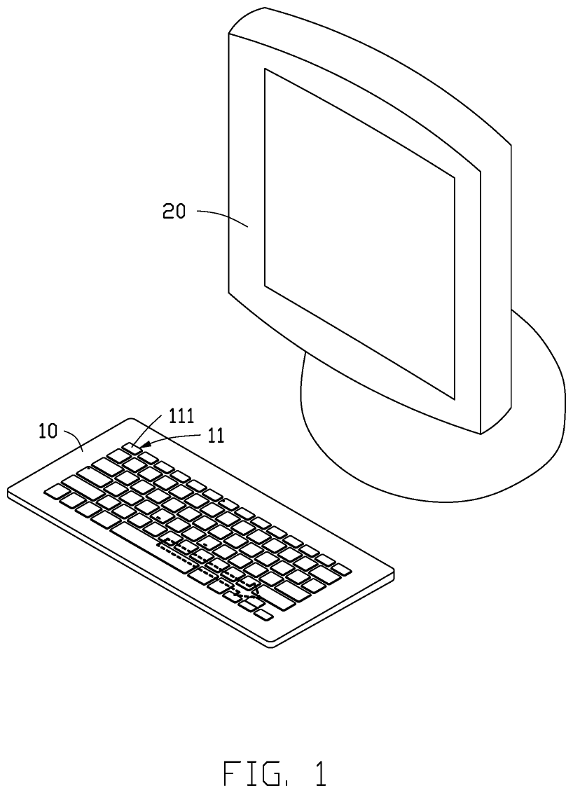

Referring to FIG. 1, a keyboard 10 provided in the present embodiment is configured to communicate with an electronic device 20. A user can input commands to the electronic device 20 by the keyboard 10. The keyboard 10 and the electronic device 20 can be connected by a wire, BLUETOOTH, or wireless network. The electronic device 20 may be a desktop display, a portable notebook, or the like. In the present embodiment, the electronic device 20 is a desktop display. The keyboard 10 and the electronic device 20 are connected by BLUETOOTH.

Referring to FIG. 1, the keyboard 10 includes a plurality of keycaps 11. The plurality of keycaps 11 are arranged in the same plane. The keycaps 11 are spaced apart from each other. Each of the keycaps 11 has an operation surface 111 for receiving touches of a user in addition to being pressed. The pressing by a user may be defined as applying approximately perpendicular pressure to the keycaps 11 on the operation surface 111. The touches of a user may be defined as a fingertip or similar touching the operation surface 111 of at least one keycap 11 or a fingertip sliding and defining a track on the operation surface 111 of at least one keycap 11. For example, referring to FIG. 1, a fingertip slides in the shape of an arrow-shaped trajectory on the operation surface 111 of several adjacent keycaps 11.

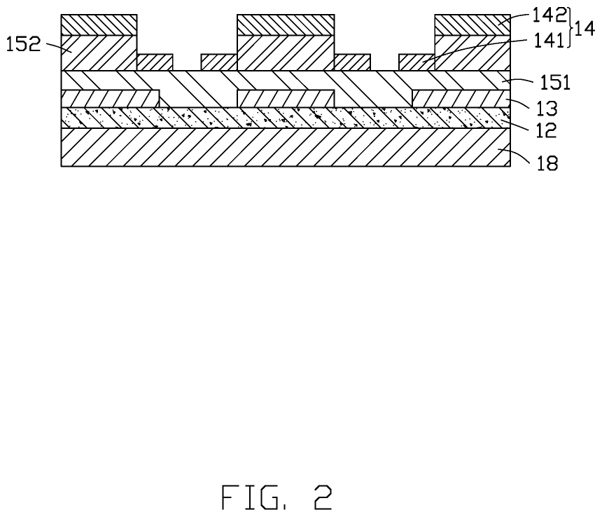

Referring to FIG. 2, the keyboard 10 further includes a substrate 12, a touch layer 13, a function component 14, a first insulating layer 151, and a second insulating layer 152. In the present embodiment, the function component 14, the first insulating layer 151, and the second insulating layer 152 of the keyboard at each of the plurality of keycaps 11 have the same structure (referring to FIG. 2).

Referring to FIG. 2, the substrate 12 is located on a side of the keycaps 11 away from the operation surface 111. The substrate 12 is made of insulating material. For example, the substrate 12 is polymethyl methacrylate (PMMA). In another embodiment of the present disclosure, the substrate 12 is made of insulating material which is flexible, to increase the deformability of the keyboard 10.

Referring to FIG. 2, the touch layer 13 is located on the side of the keycaps 11 away from the operation surface 111. The touch layer 13 is on a surface of the substrate 12 adjacent to the keycaps 11. The touch layer 13 generates a touch sensing signal if there is a touch on the operation surface 111.

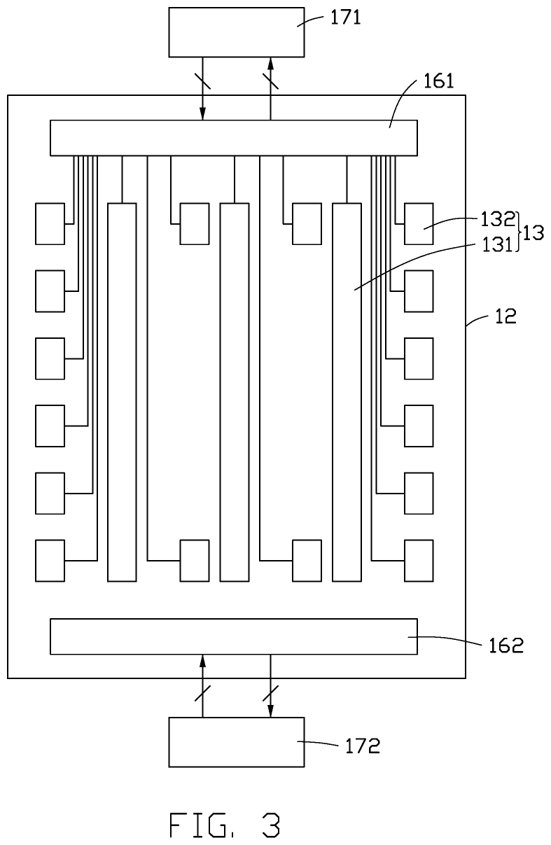

Referring to FIG. 3, the touch layer 13 includes a plurality of first electrodes 131 and a plurality of second electrodes 132. The plurality of first electrodes 131 are spaced apart from each other and electrically insulated from each other. The plurality of second electrodes 132 are spaced apart from each other and electrically insulated from each other. Each of the plurality of first electrodes 131 and each of the plurality of second electrodes 132 are electrically insulated from each other. Each of the plurality of first electrodes 131 can receive touch driving signals. Each of the plurality of second electrodes 132 can generate the touch sensing signal if there is a touch on the operation surface 111.

Referring to FIG. 3, the keyboard 10 further includes a first connection pad 161 on a surface of the substrate 12. The first connection pad 161 and the touch layer 13 are located on a same surface of the substrate 12. The first connection pad 161 is made of a conductive metal or alloy.

Referring to FIG. 3, the keyboard 10 further includes a touch controller 171. The touch controller 171 is a chip or a circuit. The touch controller 171 is electrically connected to the first connection pad 161. The first connection pad 161 is electrically connected to the touch layer 13. The touch controller 171 and the touch layer 13 are electrically connected by the first connection pad 161. Further, the first connection pad 161 is electrically connected to each first electrode 131 and each second electrode 132. The plurality of first electrodes 131 and the plurality of second electrodes 132 are electrically connected to the touch controller 171 through the first connection pad 161.

Referring to FIG. 3, the touch controller 171 outputs the touch driving signals to each of the plurality of first electrodes 131 and receives the touch sensing signals generated by each of the plurality of second electrodes 132. The touch sensing signals include information as to the touch, for example, position of a touching fingertip or a gesture such as sliding in the touch, the signal, and the information is received and recognized by the touch controller 171. The touch position of the fingertip may be caused by a single touch or multiple touches.

Referring to FIG. 2, the function component 14 is located between the plurality of keycaps 11 and the touch layer 13. The function component 14 and the touch layer 13 are electrically insulated by the first insulating layer 151. When a pressing takes place on the operation surface 111, the function component 14 generates key signals according to the pressing. The function component 14 includes a first conductive layer 141 and a second conductive layer 142 stacked thereon. The second conductive layer 142 is between the first conductive layer 141 and the plurality of keycaps 11. When a pressing takes place on the operation surface 111, the first conductive layer 141 and the second conductive layer 142 connected thereto generate the key signal. In the present embodiment, the keyboard 10 further includes a conductive elastic sheet (not shown). When a pressing takes place on the operation surface 111, the keycap 11 is pressed by the function component 14 so that the conductive elastic sheet deforms to make electrical contact with both the first conductive layer 141 and the second conductive layer 142. Thereby, the first conductive layer 141 and the second conductive layer 142 are electrically connected by the conductive elastic sheet (such behavior by the conductive elastic sheet is known in the art). Until a pressing takes place on the operation surface 111, the first conductive layer 141 and the second conductive layer 142 are electrically insulated from each other by the second insulating layer 152.

Referring to FIG. 3, the keyboard 10 further includes a second connection pad 162 on the surface of the substrate 12. The second connection pad 162 is made of metal. The keyboard 10 further includes a function controller 172. The function controller 172 is a chip or a circuit.

Referring to FIG. 2 and FIG. 3, the function controller 172 is electrically connected to the second connection pad 162. The second connection pad 162 is electrically connected to the function component 14. The function controller 172 and the function component 14 are thus electrically connected to each other through the second connection pad 162. Specifically, the second connection pad 162 is electrically connected to the first conductive layer 141. That is, the function controller 172 and the first conductive layer 141 are electrically connected through the second connection pad 162. When the first conductive layer 141 and the second conductive layer 142 are in electrical contact, the second conductive layer 142 is electrically connected to the function controller 172.

Referring to FIG. 2 and FIG. 3, the function controller 172 receives the key signal when the first conductive layer 141 and the second conductive layer 142 are in electrical contact. The key signal indicates the keycap 11 which is being pressed. The function controller 172 is configured to trigger a function according to the key signal. In general, the functions triggered by the function controller 172 are reflected on the electronic device 20 that is in communication with the keyboard 10.

Referring to FIG. 2, in the present embodiment, the substrate 12 is made of light-transmitting material. The keyboard 10 further includes a backlight source 18. The backlight source 18 emits backlight. The backlight source 18 may include a plurality of light emitting diodes, a light bar, or the like to emit the backlight. The backlight emitted by the backlight source 18 can be seen through areas between the plurality of keycaps 11, which is helpful for the user to clearly identify each keycap 11 when in a dark environment.

The keyboard 10 provided in the present embodiment includes a touch layer 13, a function component 14, a touch controller 171, and a function controller 172. The touch controller 171 is electrically connected to the touch layer 13 to obtain the touch information (the fingertip-touching position and a gesture made in the touching). The function can be triggered by the function controller 172 and the function component 14, which satisfies features demanded in human-computer interactions. The keyboard 10 includes a plurality of keycaps 11, each of the plurality of keycaps 11 has an operation surface 111. The operation surface 111 can receive pressings made in addition to touches by a fingertip. A separate touch panel is thus unnecessary, reducing the volume of the keyboard 10. Further, the keyboard 10 provided in the present embodiment includes the substrate 12 instead of a printed circuit board, allowing greater deformability in the keyboard 10, and also helps to reduce costs of the keyboard 10. In addition, the touch layer 13 and the function component 14 can be formed on the substrate 12 by screen printing.

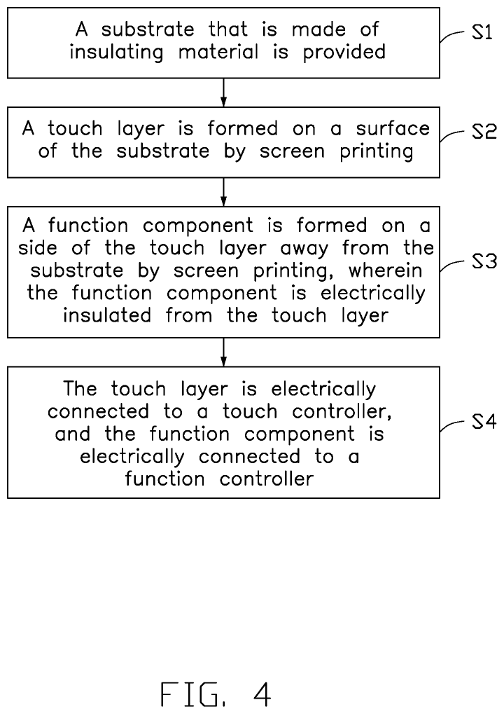

The present embodiment also provides a method for making the keyboard. Referring to FIG. 4, a flowchart of such a method is presented in accordance with an example embodiment which is being thus illustrated. The example method is provided by way of example, as there are a variety of ways to carry out the method. Each block shown in FIG. 4 represents one or more processes, methods, or subroutines, carried out in the exemplary method. Additionally, the illustrated order of blocks is by example only and the order of the blocks can change according to the present disclosure.

At block S1, a substrate that is made of insulating material is provided.

At block S2, a touch layer is formed on a surface of the substrate by screen printing.

At block S3, a function component is formed on a side of the touch layer away from the substrate by screen printing, wherein the function component is electrically insulated from the touch layer.

At block S4, the touch layer is electrically connected to a touch controller, and the function component is electrically connected to a function controller.

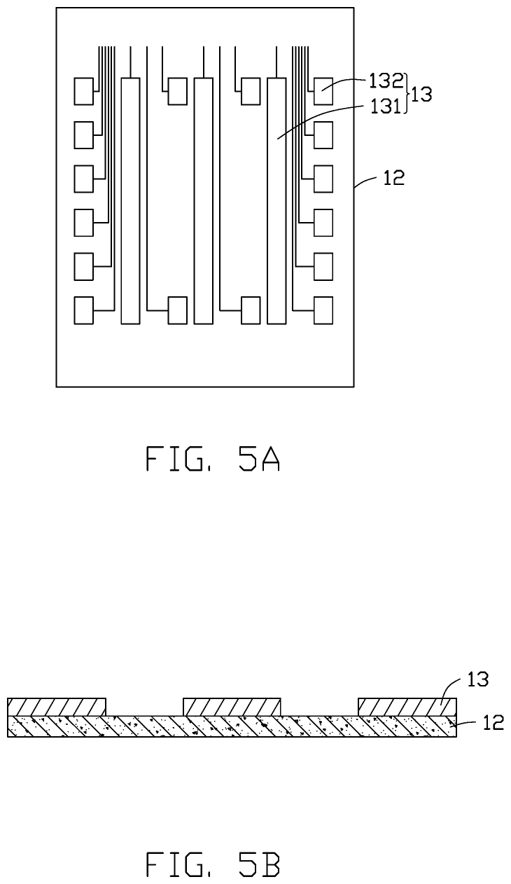

Referring to FIG. 5A and FIG. 5B, at the block S1, a substrate 12 is provided. The substrate 12 is made of insulating flexible material. At the Block S2, a plurality of first electrodes 131 and a plurality of second electrodes 132 are formed on a surface of the substrate 12 by screen printing. The plurality of first electrodes 131 and the plurality of second electrodes 132 constitute at least a portion of the touch layer 13. In the present embodiment, each of the plurality of first electrodes 131 and each of the plurality of second electrodes 132 are made of light-transmitting materials, such as indium tin oxide (ITO).

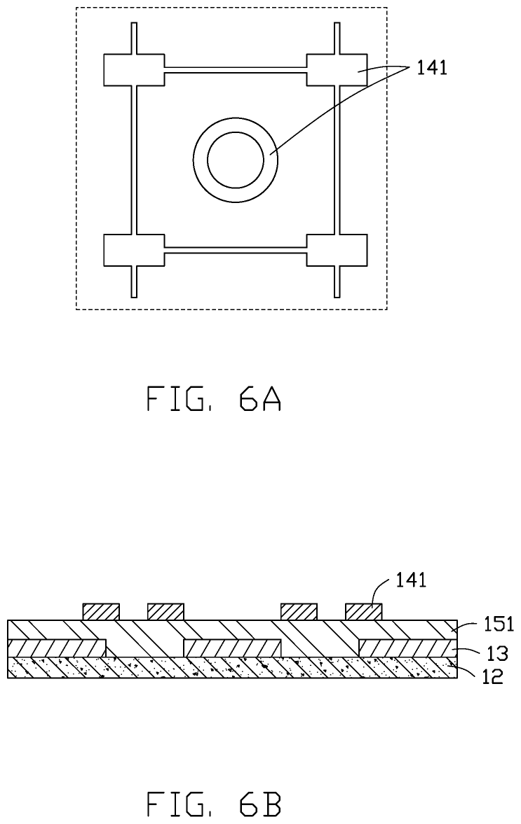

Referring to FIG. 6A and FIG. 6B, at the Block S3, a first insulating layer 151 is formed on the touch layer 13. The first insulating layer 151 is made of light-transmitting material. The first insulating layer completely covers the touch layer 13. At the Block S3, a first conductive layer 141 is also formed on the first insulating layer 151 by screen printing.

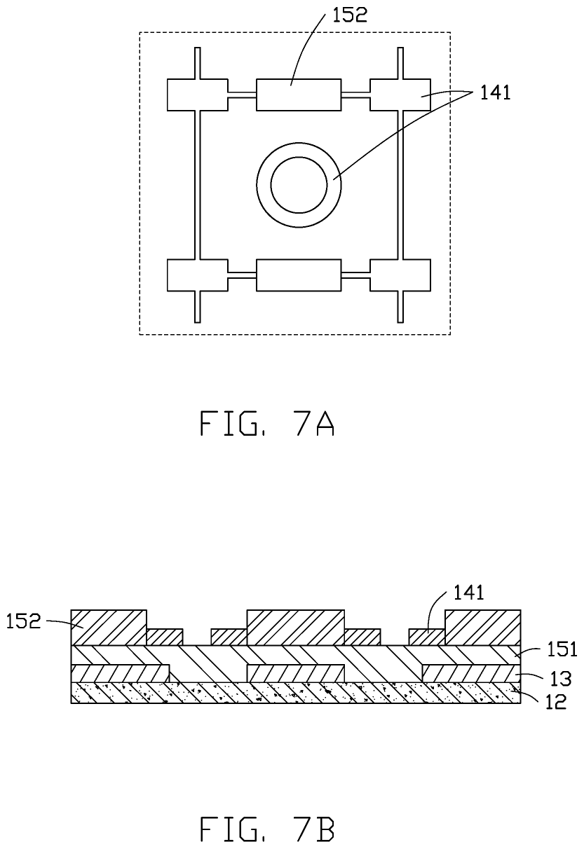

Referring to FI. 7A and FIG. 7B at the Block S3, a second insulating layer 152 is also formed on the first conductive layer 141. The second insulating layer 152 partially covers the first conductive layer 141.

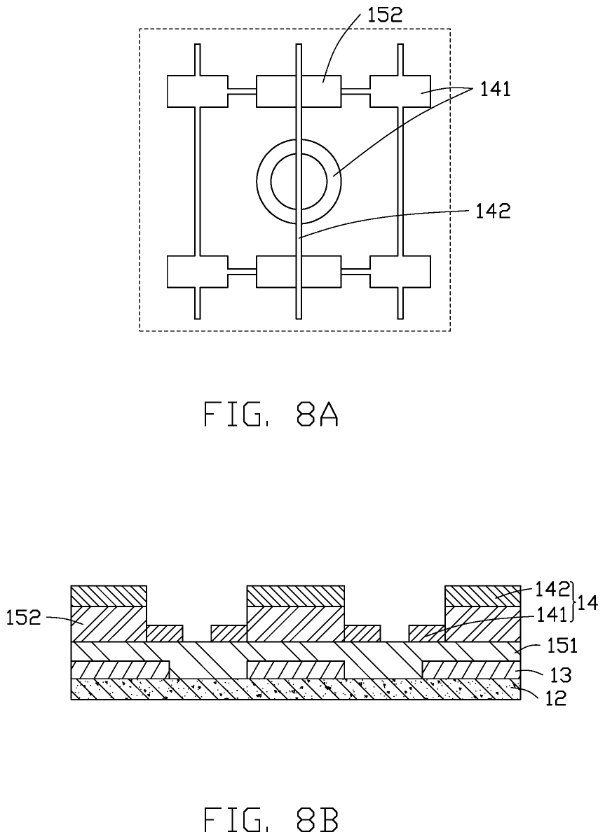

Referring to FIG. 8A and FIG. 8B, at the Block S3, a second conductive layer 142 is also formed on the second insulating layer 152 by screen printing. In the present embodiment, the first conductive layer 141 and the second conductive layer 142 constitute the function component 14.

At the Block S4, the touch layer 13 is electrically connected to the touch controller 171, the function component 14 is electrically connected to the function controller 172, and a backlight source 18 is formed on the side of the substrate 12 away from the touch layer 13. A plurality of keycaps 11 are provided on a side of the function component 14 away from the substrate 12, thereby a keyboard 10 is formed (refers to FIG. 1).

The manufacturing method of the keyboard in the present embodiment enables the keyboard 10 to get the key signal and obtain the touch information by electrically connecting the touch layer 13 to the touch controller 171 and electrically connecting the function component 14 to the function controller 172.

In addition, the manufacturing method of the keyboard in the present embodiment enables the keyboard 10 to reduce costs by replacing printed circuit boards with the substrate 12. The substrate 12 can be made of flexible material which makes the keyboard 10 to have a large deformation.

It is to be understood, even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A keyboard comprising:
a plurality of keycaps arranged in a same plane, each of the plurality of keycaps comprising an operation surface for receiving pressings and touches;
a touch layer on a side of the plurality of keycaps away from the operation surface, the touch layer configured to generate touch sensing signals according to the touches;
a function component between the plurality of keycaps and the touch layer, the function component being electrically insulated from the touch layer, the function component configured to generate key signals according to the pressings;
a touch controller electrically connected to the touch layer for obtaining touch information according to the touch sensing signals; and
a function controller electrically connected to the function component and configured for triggering key functions according to the key signals.

2. The keyboard of claim 1, wherein the touch layer comprises a plurality of first electrodes electrically insulated from each other and a plurality of second electrodes electrically insulated from each other;
the touch controller is configured to output touch driving signals, each of the plurality of first electrodes is configured to receive the touch driving signals, each of the plurality of second electrode is configured to generate the touch sensing signals.

3. The keyboard of claim 1, wherein the touch information is a touch position or touch gesture.

4. The keyboard of claim 1, wherein the function component comprises:
a first conductive layer; and
a second conductive layer between the first conductive layer and the plurality of keycaps;
the first conductive layer and the second conductive layer are electrically connected to generate a key signal if there is pressing on the operation surface, the first conductive layer and the second conductive layer are electrically insulated from each other if there is no pressing on the operation surface.

5. The keyboard of claim 1, wherein the keyboard further comprises a substrate on the side of the touch layer away from the keycap, the substrate is made of insulating material and configured for carrying the touch layer and the function component.

6. The keyboard of claim 5, wherein the substrate is made of flexible material.

7. The keyboard of claim 5, wherein the substrate is made of light-transmitting material;
the keyboard further comprises a backlight source located on a side of the substrate away from the touch layer, the backlight is configured for emitting backlight.

8. The keyboard of claim 5, wherein the substrate is made of light-transmitting material;
the keyboard further comprises a backlight source located on a side of the substrate away from the touch layer for emitting backlight.

9. A method for making a keyboard comprising:
providing a substrate that is made of insulating material;
forming a touch layer on a surface of the substrate;
forming a function component on a side of the touch layer away from the substrate by screen printing, wherein the function component is electrically insulated from the touch layer; and
electrically connecting the touch layer to a touch controller, and electrically connecting the function component to a function controller.

10. The method of claim 9, wherein providing the substrate comprises providing the substrate that is made of light-transmitting material, the g method further comprises:
providing a backlight source for emitting backlight on a side of the substrate away from the touch layer

11. The method of claim 9, wherein the method further comprises:
providing a plurality of keycaps arranged in a same plane, each of the plurality of keycaps comprising an operation surface for receiving pressings and touches.

12. The method of claim 9, wherein forming the touch layer comprises:
forming the touch layer that comprises a plurality of first electrodes electrically insulated from each other and a plurality of second electrodes electrically insulated from each other.

13. The method of claim 9, wherein forming the function component comprises:
forming the function component comprising a first conductive layer and a second conductive layer between the first conductive layer and the plurality of keycaps;
the first conductive layer and the second conductive layer are electrically connected to generate a key signal, or the first conductive layer and the second conductive layer are electrically insulated from each other.
